(19) United States
(12) Patent Application Publication
(10) Pub. No.: US 2008/0133990 A1
(43) Pub. Date: Jun. 5, 2008

(54) Scan Test Data Compression Method And Decoding Apparatus For Multiple-Scan-Chain Designs

(76) Inventors: Shih-Ping Lin, Taichung (TW); Chung-Len Lee, Taipei (TW); Jwu E. Chen, Hsinchu (TW); Ji-Jan Chen, Kaohsiung (TW); Kun-Lun Luo, Hsinchu (TW); Wen-Ching Wu, Hsinchu (TW)

Correspondence Address: LIN & ASSOCIATES INTELLECTUAL PROPERTY, INC., P.O. BOX 2339, SARATOGA, CA, 95070-0339, US

(21) Appl. No.: 11/672,044

(22) Filed: Feb. 7, 2007

(30) Foreign Application Priority Data
Nov. 30, 2006 (TW) 095144446

(51) Int. Cl. G01R 31/28

(52) U.S. Cl. 714/726

(57) ABSTRACT

Disclosed is a scan test data compression method and decoding apparatus for multiple-scan-chain designs. The apparatus comprises a on-chip decoder connected to a tester. The decoder includes a decoding buffer configured as a multilayer architecture, a controller, and a switching box for receiving a shift signal or a copy signal. The decoding buffer is used to store decoded test data. While the decoder decodes the encoded data, it transmits control signals to both the decoding buffer and the switching box from the controller, and sends the decoded data to scan chains of a CUT for testing through the decoding buffer. This invention has the advantages of simple encoding method, high compression rate, low power consumption in testing, and without the fault coverage loss.

### FIELD OF THE INVENTION

The present invention generally relates to a scan test data compression method and decoding apparatus, applicable to multiple-scan-chain designs.

### BACKGROUND OF THE INVENTION

As the very large scale integrated circuit (VLSI) technology rapidly grows, the complexity of system-on-chip (SoC) design increases, and the amount of related test data also increases greatly. To prevent the test cost from increasing caused by large amount of data, numerous test data compression methods have been proposed. As shown in FIG. 1, these compression methods first compress/encode test pattern 101 into encoded test data 103, and then use an embedded decompressor/decoder 105 to decode the encoded data for transmission to scan chains 109 of circuit-under-test (CUT) 107 for test. The input data of the decoder comes from the tester, and its outputs are connected to scan chains. The number of the inputs of the decoder is usually less than the number of outputs, and thus few input pins can support large number of scan chains. The test data compression technologies can be divided into four types according to the design of decoders.

The first type is the combinational-type decoder. The decoding circuit is composed of the combinatory logical gates, such as AND, XOR, connected by interconnection lines. This type of decoder creates the dependency between the inputs and the outputs. Therefore, the number of test patterns that can be generated is limited. Even if the automatic test pattern generator (ATPG) can find the test pattern to detect faults, the decoder may not be able to generate corresponding test pattern, and thus result in fault coverage loss. This method also randomly fills the unspecified bits to generate test pattern, which causes a large amount of power consumption.

The second type is the sequential-type decoder. The decoder uses linear feedback shift register (LFSR) and phase shifter to decode. This type is more flexible so that it has a higher compression rate than the first type, but has the same disadvantages of high power consumption and fault coverage loss because of the limitation of the decoder.

The third type is the codeword type. The type uses the conventional data encoding methods to encode test data, such as Huffman coding, or run-length coding. The decoder must implement the corresponding decoding function, and the design must take hardware area into consideration to reduce the area cost. This type may result in the synchronization overhead with the tester due to the mismatch between the tester's transmission speed and the decoding speed. This type is not convenient in supporting multiple-scan-chain designs.

The fourth type is the bit-flip type. This type flips the different bits or region in two test patterns to accomplish data compression. To flip the bits or region in a test pattern, the design relies on the hardware. The conventional technique is to use embedded processor and memory, or random access scan (RAS). The bit-flip design must concern the hardware area, especially for the RAS, which may be considerably expensive. This type is suitable for highly correlated test patterns.

### SUMMARY OF THE INVENTION

The examples of the present invention may provide a scan test data compression method and decoding apparatus for multiple-scan-chain designs to effectively overcome the problem in conventional test data compression techniques.

The scan test data compression method can transform the scan test pattern into an encoded data, and use a decoder circuit to decode the encoded data. The amount of encoded data is much less than the original data, and the data transmission time is reduced.

The decoder may include a controller, a decoding buffer for receiving control signals from the controller, and a switching box. An external tester is connected to the decoder through a test channel, and the encoded data is transmitted to the decoder through the test channel. The controller in the decoder generates control signals for switching box and decoding buffer. The encoded data is decoded through shift and copy to restore the pattern compatible to the original test pattern. The decoded data is transmitted to the scan chains of the circuit-under-test (CUT) for testing. The decoding buffer reduces the internal changes in the scan flip-flop by repetitively sending the same bit slice to CUT, and further reduces the power consumption for testing.

The decoding buffer comprises data flip-flops, and can form different layers architecture with switching box when designed. Each layer can group the flip-flops into groups. Each lower layer can be further divided into higher layers by dividing each group into smaller groups.

With the architecture of the decoding apparatus for scan test data, the compression method for the multiple-scan-chain designs of the present invention may use the decoding buffer and the switching box to control shift and copy mode to achieve the data decoding, transfers the data to CUT so that CUT can receive test pattern for scan test.

The present invention only requires a test channel of tester to support multiple scan chains. The compression method is simple, and can be flexibly used in a conventional design flow or integrated into ATPG to provide higher efficiency. The hardware cost of the decoder of the present invention is inexpensive, and without the problem of fault coverage loss.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows a schematic view of a conventional test data compression technique.

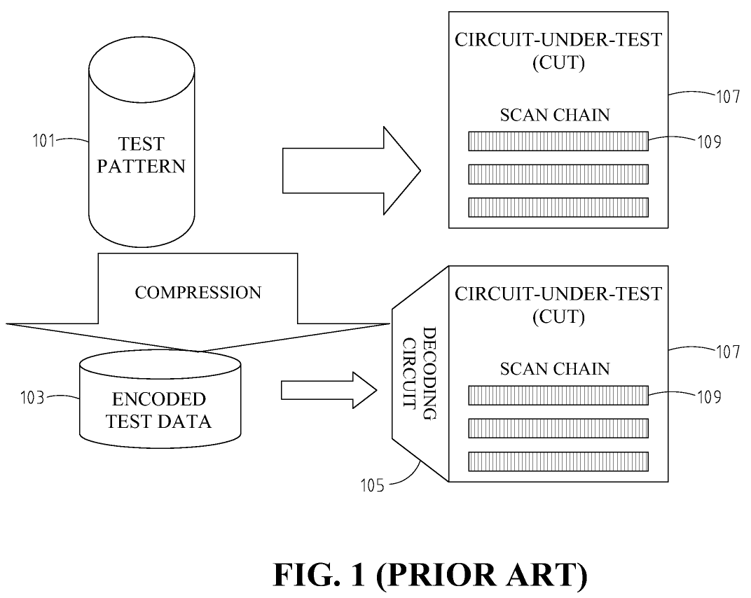

FIG. 2 shows a structure of a decoding apparatus for scan test data of a multiple-scan-chain design according to the present invention, and the applied scan test environment thereof.

FIG. 3 shows an example of realizing an L-layer decoding buffer, where L=3.

FIG. 4 shows the use of a switching box to support shift mode and copy mode.

FIG. 5 shows an example for realizing a 3-layer switching box, where the first, second, and third layer has 8, 4, and 2 bits respectively.

FIG. 6 shows an example of using shift mode and copy mode to transmit test data according to the present invention, where the first, second, and third layer has 8, 4, and 2 bits respectively.

FIG. 7 shows a flowchart illustrating the decoding process of multilayer data copy according to the present invention.

FIG. 8 shows a flowchart illustrating the encoding process of test scan data according to the present invention.

FIG. 9 shows the detailed flow of FIG. 8.

FIG. 10 shows another example describing the encoding/decoding relation, where the layer structure of decoding buffer is the same as FIG. 6.

FIG. 11 shows a flowchart illustrating the steps of generating deterministic patterns according to the present invention.

### DETAILED DESCRIPTION OF THE PREFERRED EMBODIMENTS

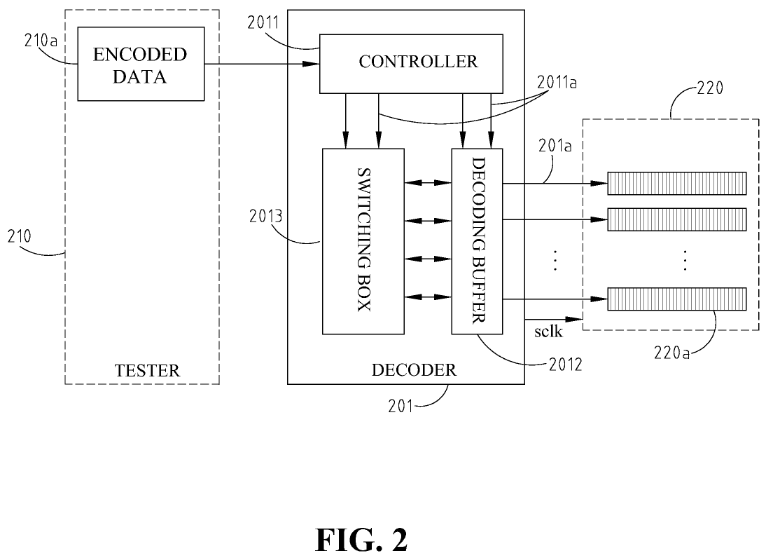

FIG. 2 shows a structure of a decoding apparatus for scan test data of a multiple-scan-chain design, and the applied scan test environment thereof. As shown in FIG. 2, the decoding apparatus for scan test data comprises a decoder 201, connected to an external tester 210. The decoder 201 further includes a decoding buffer 2012, a controller 2011 and a switching box 2013.

An external tester 210 inputs an encoded data 210a to the decoder 201. The controller 2011 of the decoder 201 generates a plurality of control signals 2011a for switching box 2013 and decoding buffer 2012 according to input encoded data 210a. Based on the control signals 2011a, the decoder 201 uses a decoding algorithm, through controlling shift and copy modes, to decode the encoded data 210a, asserts the scan clock sclk of a CUT 220, and transmits the decoded data 201a through the decoding buffer 2012 to the multiple scan chains 220a of the CUT 220 for testing.

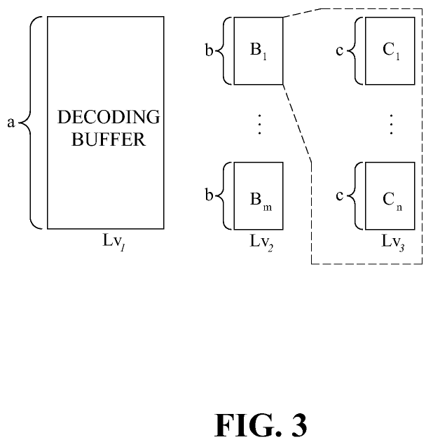

The decoding buffer 2012 is configured as a multilayer structure. FIG. 3 shows an example of realizing an L-layer decoding buffer, where L=3. As shown in FIG. 3, the decoding buffer includes a plurality of data flip-flops (DFFs), grouped into three layers indicated as Lv1, Lv2, and Lv3 respectively. The number of the DFFs is denoted as a.

The multilayer structure is described as follows. The decoding buffer is first treated as the first layer, Lv1. The a DFFs are grouped into m groups, with each group having b DFFs. In other words, m*b=a, and these m groups B₁-Bₘ form the second layer, Lv2. Similarly, each group of Lv2 is further divided into n groups C₁-Cₙ, with each group having c DFFs. That is, n*c=b, and these groups form the third layer, Lv3. More layers can be obtained if further division is performed.

According to the present invention, the switching box 2013 can provide the data transmission paths between DFFs after receiving the control signal 2011a. Based on control signal 2011a, each data in the DFF of decoding buffer 2012 can be transmitted to different destination DFF.

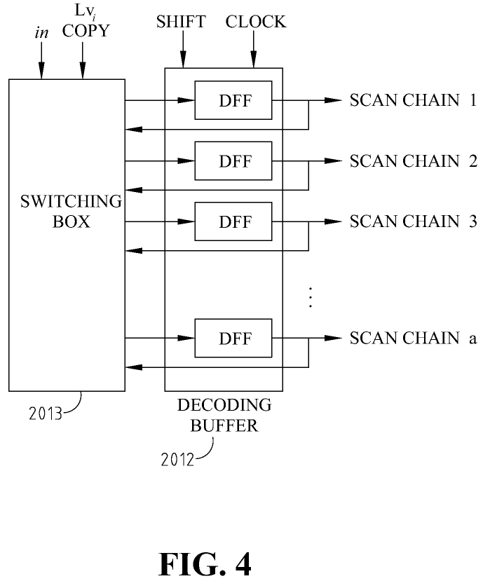

The decoding buffer 2012 has two operation modes, i.e. shift mode and copy mode. FIG. 4 shows the use of the switching box 2013 supporting these two modes. In shift mode, the DFF becomes the shift register, and the external data is inputted from the in pin sequentially. In copy mode, the current layer must be known and the data of each group is copied from the previous group; for example, the data of group C₂ is copied from group C₁, and the data of the first group remains unchanged.

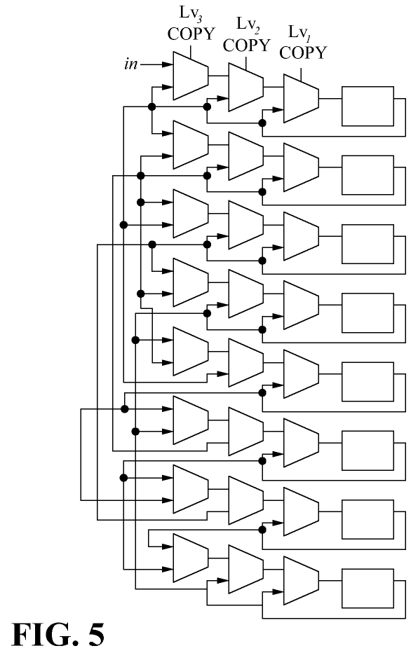

With the design of the switching box 2013, decoding buffer 2012 can have different layer architecture. The switching box 2013 can be implemented with multiplexers. FIG. 5 shows an example for realizing a 3-layer switching box, where a=8, b=4, and c=2.

Through copy mode, the test data can be quickly loaded into decoding buffer and transmitted to CUT to achieve data compression. When a bits of data are decoded and stored in the decoding buffer, it indicates a bit slice is ready. Then, the decoder asserts the scan clock, sclk, of CUT, and the bit slice is transmitted to the scan chains of CUT.

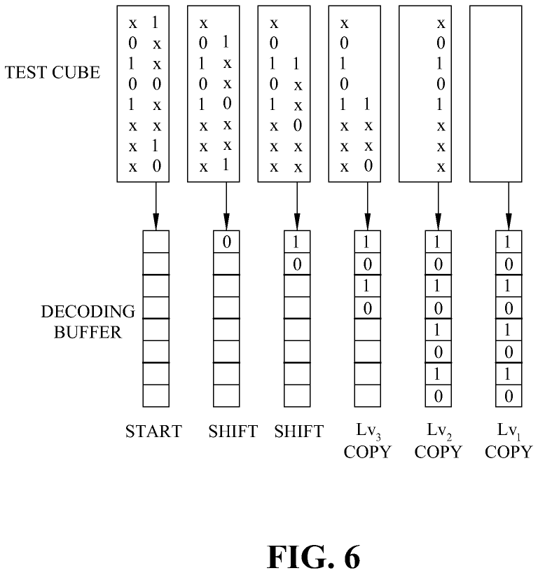

FIG. 6 shows an example to describe the operation of aforementioned shift mode and copy mode. First, suppose a 16-bit test pattern with don't-care-bit, also called test cube, will be transmitted to a CUT with 8 scan chains. Then, a 3-layer decoding buffer with 8, 4, 2, DFFs for each group of the first, second, and third layer, respectively, is applied.

Referring to FIG. 6, as there is no data in the decoding buffer when decoding starts, the first step is to shift first bit “0”, and the second step is to shift the second bit ‘1” into the decoding buffer. As the first two bits “01” are compatible with the third and fourth bits, the third step is to copy the third and fourth bits from first and second bits, known as the Lv3 copy. Similarly, bits 5-8 are compatible with bits 1-4, and the Lv2 copy is performed to copy the first four bits into the 5-8 bits. After the copy, the 8 bits are transmitted to CUT since a bit slice is ready. Similarly, bits 9-16 are compatible with the first 8 bits, and Lv1 copy is performed; thus, the 16-bit test cube is completely transmitted to the CUT.

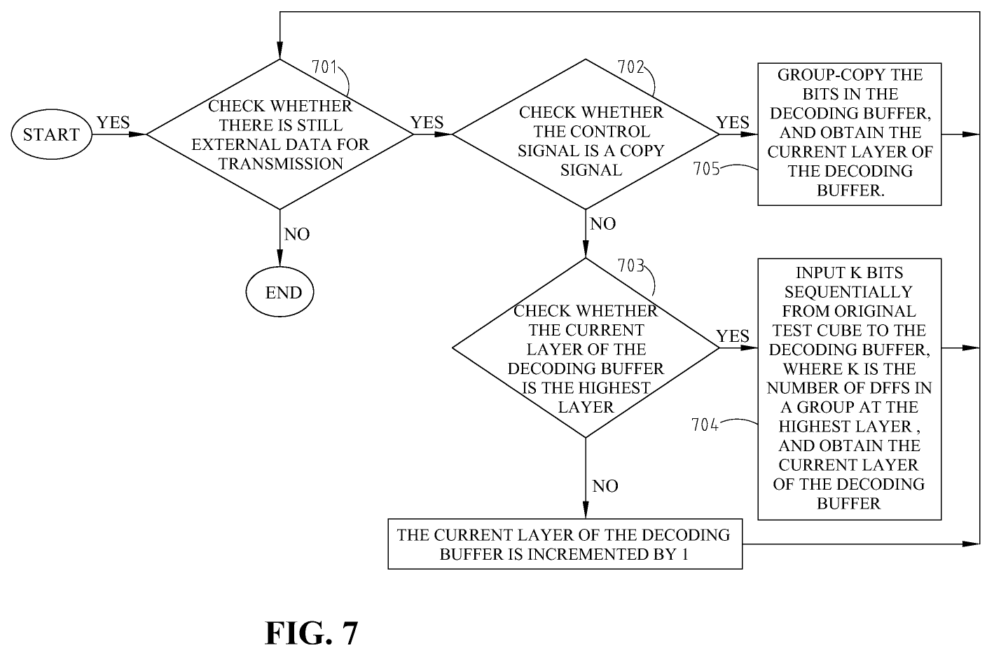

FIG. 7 shows a flowchart illustrating the decoding process of multilayer data copy according to the present invention. Step 701 is to check whether there is still external data for transmission. If no, the decoding process ends. Otherwise, step 702 is to check whether the control signal is a copy signal. If the control signal is not a copy signal, step 703 is to check whether the current layer of the decoding buffer is the highest layer. If the current layer is the highest layer, step 704 is to input k bits sequentially from original test cube to the decoding buffer, where k is the number of DFFs in a group at the highest layer, and then obtain the current layer of the decoding buffer, followed by returning to step 701. If not the highest layer, the current layer of the decoding buffer is incremented by 1, and followed by returning to step 701.

If it is a copy signal in step 702, step 705 is to group-copy the bits in the decoding buffer and obtain the current layer of the decoding buffer.

It can be observed in the above decoding process that the test data is not transmitted to the CUT in every test cycle, but only when the decoding buffer is filled with a bit slice. This is different from the conventional test data decoding technique. In addition, the present invention does not have the problem of synchronization because the tester is not stopped during the entire decoding process.

Correspondingly, the present invention utilizes the data compatibility in the original test cube to encode the shift and copy signals. The shift signals are for inputting original test data sequentially, and the copy signals are for group-copying the data in the decoding buffer to generate a test pattern compatible with the original test cube.

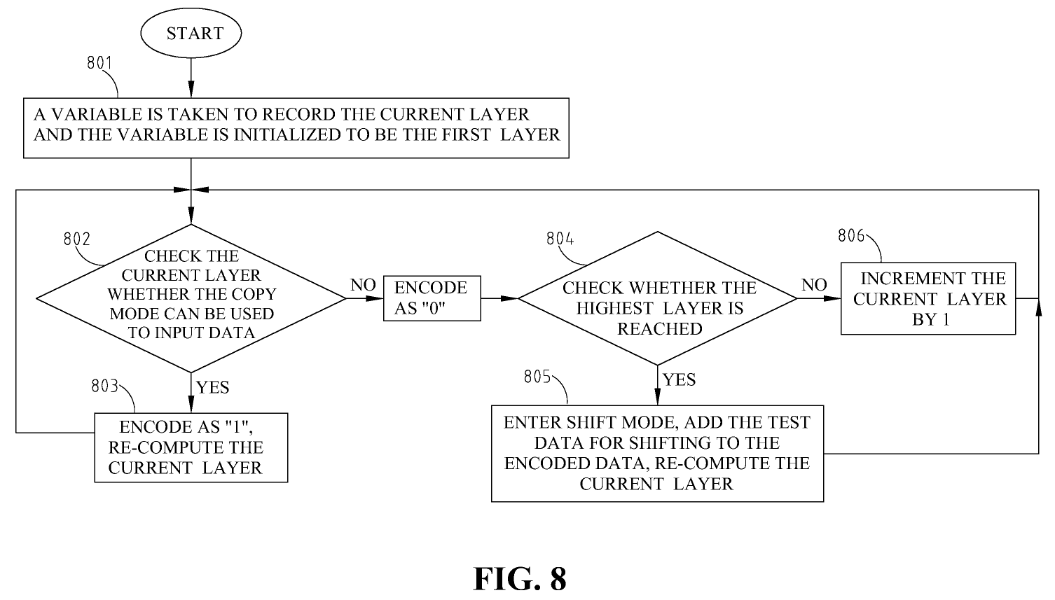

FIG. 8 shows a flowchart illustrating the encoding process of test scan data according to the present invention. In step 801, a variable is taken to record the current layer, and the variable is initialized to be the first layer. Step 802 is to check in the current layer whether the copy mode can be applied to input data. If so, step 803 is to encode as “1”, re-compute the current layer, and return to step 802; otherwise, a bit “0” is encoded and followed by step 804. In step 804, whether the highest layer is reached will be checked. If the highest layer is reached, step 805 is to enter shift mode, add the test data for shifting to the encoded data, re-compute the current layer, and return to step 802; otherwise, step 806 is to increment the current layer by 1, and return to step 802.

In the above process, the current layer may be changed after a shift or copy operation. With a counter to record the current location of the decoding buffer, the current layer can be computed.

The example in FIG. 6 can be used to describe the encoding process. The current layer is initially set to be 1. The result in checking copy mode shows that there is no data in the decoding buffer, and therefore the copy mode cannot be applied. Hence, a control bit “0” is encoded, and the process enters the second layer. The second check shows that the copy mode cannot be applied, and the process enters the third layer, where the copy mode is not applicable again. Therefore, two control bits “00” are added. At this point, the highest layer is reached, and the shift mode is adopted. Two data bits “01” for shifting are added to the encoded data. After the shift mode is completed, step 802 is taken again to check the copy mode, and find that Lv3 copy can be applied to input the following two bits. Thereafter, the current layer is changed to the second layer. Similarly, the Lv2 copy and Lv1 copy are applied to complete the input of entire data. The final encoded data is “00001111”, where the middle “01” are shifted data, and the first three and last three are control bits of copy mode. In comparison with the original 16 bits, the encoded data is 8 bits, and the compression rate is as high as 50%.

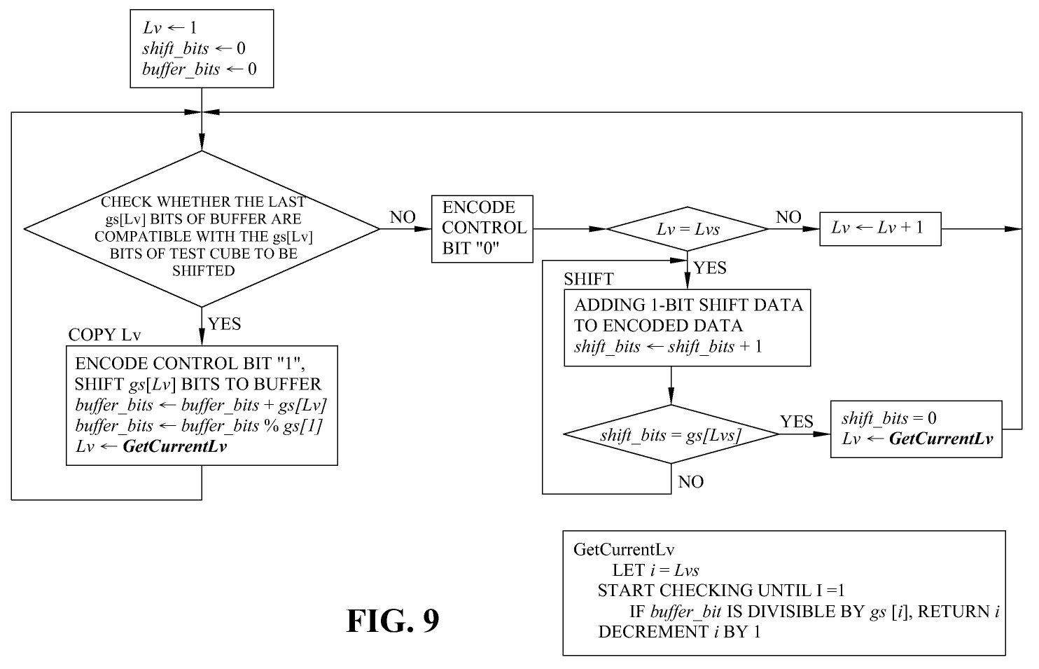

FIG. 9 shows the detailed flow of FIG. 8, where the GetCurrentLv is used for checking the current layer, Lvs is the number of layers in the structure, gs is an array for recording the size of the group in each layer, Lv is the current layer, shift_bit is the number of bits already input in the shift mode, and buffer_bit is the bit position already input in a bit slice.

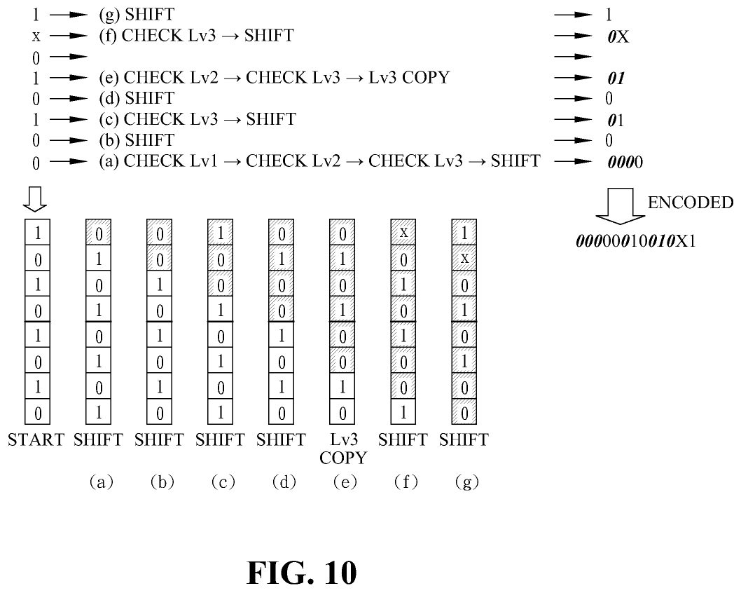

FIG. 10 uses an example to explain the relation between encoding and decoding, where the decoding buffer has the same layer structure as FIG. 6. As shown in FIG. 10, a new bit slice 1X010100 is to be encoded using the encoding process presented in FIG. 9. The arrow next to the bit indicates the encoding/decoding operation when the bit is reached.

For the first bit, marked as (a), the first step is to check whether the first layer can be copied. Because the copy can not be done, the control bit “0” is encoded. As the second layer and the third layer cannot be copied neither, two control bits ‘00” are encoded, and the shift mode is entered. Finally, a data bit “0” is inputted. The most right part for each bit shows the corresponding encoded data. For the bit marked as (a), the encoded data is three control bits “000” and a shift data bit “0”.

For the second bit, marked as (b), another data bit is added to the encoded data. For the bit marked as (c), Lv3 copy is checked for applicability. For the bit marked as (e), Lv2 copy is first checked for applicability, and found Lv3 copy can be applied; thus the control bits “01” are encoded. The final encoded data is “000000010010X1”, including three shift modes and an Lv3 copy mode.

The multilayer data copy can be applied to test data compression in two ways. The first is to compress the automatic test pattern generator (ATPG) generated test patterns, and the second is to integrate the multilayer data copy compression technique into ATPG to improve the encoding efficiency. The present invention further includes an automatic test pattern generator for generating highly compressible test patterns, called multilayer data copy pattern generator (MDCGEN).

To reduce the power consumption for scan testing, the present invention increases the probability of Lv1 copy as much as possible. Because when the Lv1 copy is performed, the two neighboring bit slices are identical, and the number of the bit flips of scan DFF will not increase. Therefore, the increase in the number of bit flips of scan chain shift can be avoided. On the other hand, to improve the test compression rate, the present invention applies Lv1 copy as much as possible to reduce the number of transmitted data. Therefore, both have the same requirement to achieve low power consumption and high test data compression rate.

In the present invention, the ATPG uses two stages to generate test patterns. The first stage is to generate random test patterns. The random test patterns can test the easy-to-detect faults of the CUT. After the random test pattern testing, the second stage is to generate deterministic patterns targeting the faults that cannot be easily tested by random test patterns.

The random test patterns of the first stage are generated by randomly generating a bit slice for the decoding buffer, and repeatedly inputting the same bit slice to the scan chain of CUT. That is, applying the Lv1 copy to repeatedly input bits until the scan chains are entirely loaded, or change to another bit slice when partially loaded to generate patterns with more randomness. The generated random test patterns can first test the easy-to-detect faults of CUT. Based on the generated random test patterns, the present invention can easily bust the fault coverage to a certain level with low scan-in power consumption.

After completing the random test pattern testing, the deterministic patterns of the second stage are generated. A test cube list (TCL) is used to store the generated test cubes throughout the following explanation. First, a test cube is generated targeting for undetected faults. If the generated test cube is compatible with the test cubes in the TCL, the best compatible test cube is selected for merging with the generated test cube. The definition of the best compatibility is the best compression rate without large number of bit flips after being merged with the generated test cube. After that, the merged test cube is applied for fault simulation to remove the additional detected faults, and steps are repeated. If the generated test cube is not compatible with the test cubes in the TCL, the generated test cube is added to the TCL.

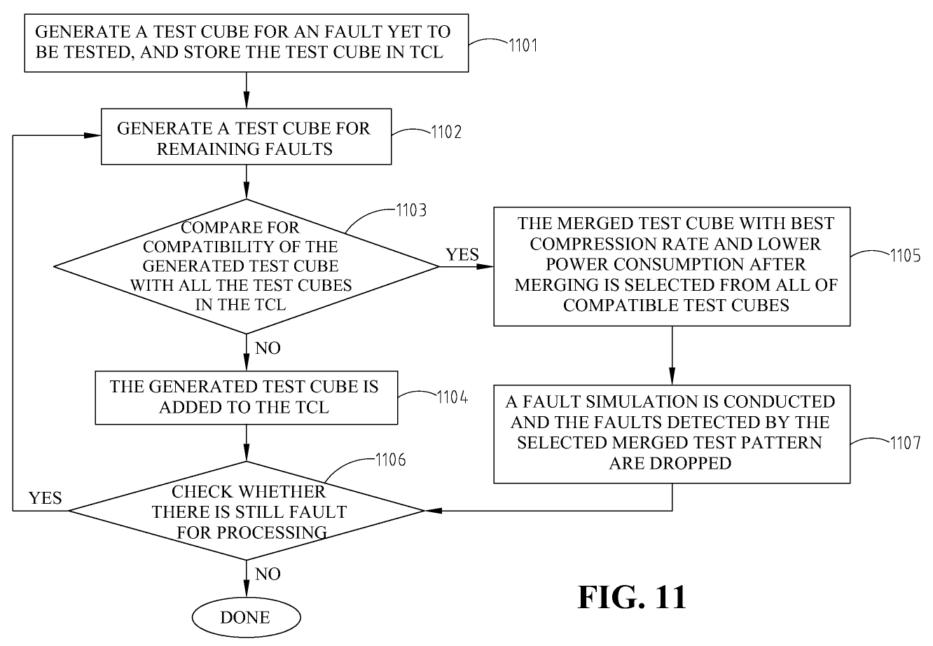

FIG. 11 shows a flowchart illustrating the detailed steps of generating the deterministic patterns. Step 1101 is to generate a test cube for a fault yet to be tested, and store the test cube in TCL. Step 1102 is to generate a test cube for remaining faults. Step 1103 is to compare for compatibility of the generated test cube with all the test cubes in the TCL. If not compatible, the generated test cube is added to the TCL, as shown in step 1104. If compatible with some test cubes in the TCL, the merged test cube with best compression rate and lower power consumption after merging is selected from all of compatible test cubes, as shown in step 1105.

After step 1104, step 1106 is to check whether there is still fault for processing. If so, return to step 1102; otherwise, the process for deterministic pattern generation ends.

After step 1105, a fault simulation is conducted and the faults detected by the selected merged test pattern are dropped, as shown in step 1107, then followed by returning to step 1106.

The experimental results of the present invention include the comparison of compression rate and the power consumption of the test patterns. As the results show, in comparison with the conventional techniques, the compression method according to the present invention is simple, provides high compression rate, consumes less power during the test, and is without the problem of fault coverage loss.

In summary, the present invention provides a scan test data compression method and decoding apparatus for multiple-scan-chain designs. The present invention only requires a test channel of the tester to support large amount of internal scan chains. The compression method according to the present invention can transform the conventional scan test patterns into encoded data. The amount of encoded data is much less than the original data; therefore, the data transmission time is reduced. In addition, by using the decoding buffer of the decoder, the controller can restore the encoded data to a pattern that is compatible with the original test pattern, and transmit to the CUT. The decoding buffer applies Lv1 copy to transmit the same bit slice repeatedly to CUT so as to reduce the number of transitions of scan registers, and also reduce the power consumption during test.

The present invention can be applied to the compression of the test patterns generated by ATPG, or integrated into the pattern generation process of ATPG to improve the encoding efficiency. The compression method is without the problem of fault coverage loss. Because the compression method does not randomly fill don't-care bits to generate test patterns, the power consumption during the test is lower.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A decoding apparatus of scan test data for multiple scan chains, comprising:
a decoder connected to a tester, said decoder further including:
a decoding buffer configured as a multilayer structure, for storing partial test data generated during decoding;
a controller for generating a plurality of control signals; and
a switching box for receiving said plurality of control signals;
wherein said decoder decodes a plurality of encoded data through a decoding algorithm, said control signals control said switching box and said decoding buffer through a shift mode and a copy mode, and said decoded data are transmitted to a plurality of scan chains of a circuit-under-test for testing.

2. The decoding apparatus as claimed in claim 1, wherein said plurality of control signals have two types of modes, and they are shift mode and copy mode.

3. The decoding apparatus as claimed in claim 1, wherein said decoding buffer includes a plurality of data flip-flops (DFFs), and is configured as a multilayer structure.

4. The decoding apparatus as claimed in claim 1, wherein said switching box is implemented with at least one multiplexer.

5. The decoding apparatus as claimed in claim 3, wherein said switching box supports said shift mode and said copy mode, and controls the data transmission paths between said plurality of DFFs.

6. The decoding apparatus as claimed in claim 3, wherein each DFF of said plurality of DFFs has two types of operation modes, and they are shift mode and copy mode.

7. A compression method of scan test data for multiple-scan-chains designs, comprising the steps of:
configuring a decoding buffer as a multilayer structure, and integrating said decoding buffer into a decoder, said decoder receiving an encoded data from a tester;
generating a control signal according to said encoded data; and
based on said control signal, decoding said encoded data through a decoding method and the controlling of a shift mode and a copy mode, and transmitting said decoded data to a plurality of scan chains of a circuit-under-test (CUT) for testing.

8. The compression method as claimed in claim 7, wherein said decoding buffer includes a plurality of data flip-flops (DFFs), and said plurality of DFFs are grouped into multiple layers.

9. The compression method as claimed in claim 7, wherein said control signal is one of shift signal and copy signal.

10. The compression method as claimed in claim 9, wherein said shift signal is for inputting original test data sequentially, and said copy signal is for multilayer group-copying the bits stored in said decoding buffer, and encoding/decoding into a test pattern compatible with an original test cube.

11. The compression method as claimed in claim 10, wherein said encoding step for multilayer group-copying on said original test cube includes the steps of:
taking a variable to record the current layer, and initializing said variable to be the first layer;
at each layer, checking whether said copy mode being applicable to input data;
if said copy mode being applicable to input data, encoding as “1”, re-computing the current layer, returning to said step of checking whether said copy mode applicable to input data;
if said copy mode being not applicable to input data, a “0” being encoded and followed by checking whether the highest layer being reached;
when reaching the highest layer, entering said shift mode, encoding data for shifting, re-computing the current layer, and returning to said step of checking whether copy mode applicable to input data; and
if not reaching the highest layer, incrementing the current layer by 1, and returning to said step of checking whether said copy mode applicable to input data.

12. The compression method as claimed in claim 9, wherein said decoding method further includes the steps of:
checking whether existing external data for transmitting;
if no data for transmitting, said terminating said decoding method; otherwise, checking whether said control signal being said copy signal;
if said control signal being said copy signal, group-copying the bits stored in said decoding buffer;
obtaining the current layer of said decoding buffer, and returning to said step of checking whether existing external data for transmitting;
if said control signal being not said copy signal, checking whether the current layer of said decoding buffer being the highest layer;
if the current layer of said decoding buffer being the highest layer, inputting k bits sequentially from said original test cube to said decoding buffer, obtaining the current layer of said decoding buffer, k being the number of DFFs in the highest layer group, and returning to said step of checking whether existing external data for transmitting; and
if the current layer of said decoding buffer being not the highest layer, incrementing the current layer of said decoding buffer by 1, and returning to said step of checking whether existing external data for transmitting.

13. The compression method as claimed in claim 7, further comprising a step of automatically generating one or more test patterns.

14. The compression method as claimed in claim 13, wherein said step of automatically generating one or more test patterns includes a first stage and a second stage, said first stage generates at least a random test pattern for testing, said random test pattern is for testing one or more easy-to-detect faults in the CUT, after said first stage, said second stage generates one or more deterministic test patterns for testing one or more faults difficult to be tested by said random test pattern.

15. The compression method as claimed in claim 14, wherein said first stage further includes the steps of:
randomly generating a first bit slice for said decoding buffer; and
applying said copy mode at the first layer to repeatedly inputting said first bit slice to a plurality of scan chains of said CUT until said plurality of scan chains of said CUT being entirely loaded; or loading said plurality of scan chains of said CUT to a part, then applying said copy mode at the first layer by a second bit slice to repeatedly inputting said second bit slice.

16. The compression method as claimed in claim 15, wherein said copy mode at the first layer repeatedly inputting is to repeatedly inputting the same bit slice into said plurality of scan chains of said CUT.

17. The compression method as claimed in claim 14, wherein said step of generating a deterministic pattern further includes the steps of:
generating a first test cube for a fault yet to be tested, recording said test cube in a test cube list (TCL);
generating a second test cube for the remaining faults to be tested;
comparing for compatibility of the generated second test cube with all the test cubes in said TCL;
if a compatible test cube existing, trying to merge said compatible test cube with said generated second test cube, selecting a merged pattern with best compression rate and lower power consumption, and conducting a fault simulation to drop the faults detected by the selected merged test pattern;
if there is no compatible test cube, adding said generated second test cube to said TCL;
checking whether existing one or more faults yet to be processed; and
repeating the above steps from said generating said second test cube for the remaining faults to be tested up to said checking whether existing said one or more faults yet to be processed, until all faults being processed.
